(19) United States
(12) Patent Application Publication
(10) Pub. No.: US 2025/0214830 A1
(43) Pub. Date: Jul. 3, 2025

(54) SUBSTRATE COMPRISING A BASE AND AN INTEGRATED GETTER FILM FOR MANUFACTURING MICROELECTRONIC DEVICES

(71) Applicant: SAES GETTERS S.P.A., Lainate MI (IT)

(72) Inventors: Alessandro GALLITOGNOTTA, Origgio VA (IT); Luca MAURI, Cesano Maderno MB (IT)

(73) Assignee: SAES GETTERS S.P.A., Lainate MI (IT)

(21) Appl. No.: 18/853,165

(22) PCT Filed: Mar. 23, 2023
(86) PCT No.: PCT/EP2023/057512

§ 371 Date: Oct. 1, 2024

(30) Foreign Application Priority Data
Apr. 1, 2022 (IT) 102022000006506

(51) Int. Cl. B81B 7/00; B01J 20/02; C23C 14/16; C23C 14/34

(52) U.S. Cl. CPC B81B 7/0038; B01J 20/02; C23C 14/16; C23C 14/34

(57) ABSTRACT

A substrate comprising a base and an integrated coated getter film for manufacturing microelectronic, microoptoelectronic or micromechanical devices, wherein the composition of said getter film comprises Zr in an amount comprises between 65% at and 80% at, V in an amount comprised between 15% at and 25% at, a third element selected between Al and Fe in an amount comprised between 2% at and 15% at, and the getter film structure is characterized by surface roughness values comprised between 2 and 20 nm.

The present invention relates to a substrate comprising a base and an integrated coated getter film for manufacturing microelectronic, microoptoelectronic or micromechanical devices.

One of the main technical issues related to Microelectromechanical Systems (MEMS), also called integrated electronic circuits (ICs), is related to their packaging solutions since many devices require a vacuum and/or a controlled atmosphere in order to properly operate and maintain their lifetime, which can be as long as 15 or 20 years.

In some kinds of integrated circuits such as ferroelectric memories, the control of gas diffusion, specifically hydrogen, is crucial to avoid the corruption of the whole ferroelectric material.

In this field, also IR sensors and microbolometers require a specific control and elimination of gases. For example, in the case of IR sensors, these gases can either sorb part of the incident radiation or transport heat by convection from the window to the array of pixels constituting the sensing elements of the device, with relevant consequences on the measurement accuracy and, in the worst case, with malfunctioning or no working at all of the device.

The most used solution to keep the inner pressure of a hermetically sealed device and, at the same time, to control and remove the gases entering in a MEMS device, involves the use of getter materials. These materials are generally represented by metals such as zirconium, titanium, vanadium, niobium, tantalum or alloys thereof which may further comprise transition elements, rare earths or aluminum; said materials have a strong chemical affinity towards gases such as hydrogen, oxygen, water, carbon oxides and in some cases nitrogen.

One of the main challenges related to the need to have a getter material inside the MEMS devices is represented by the small dimension required by these sensors; said issue for example can be solved by introducing a thin film getter inside the volume of the devices.

The getter thin film can be deposited using a sputtering technique that is particularly advantageous when applied to the manufacture of supports with integrated getter materials to be used in the production of microelectronic devices, such as those described in patents U.S. Pat. Nos. 7,180,163 and 6,897,551, both in the name of the applicant.

Also US20090301610 describes a process for depositing on a substrate a thin film of metal alloy and the relative metal alloys.

It is important to point out that the standard systems require a heating process to activate the getter material, which, depending on the getter composition, is typically in the range of 400° C. to 900° C. Unfortunately, these activation temperatures can lead to the spoilage and damage of some device components, or damage of the whole sensor, such as the hermetic joints, the antireflection coatings, sensitive elements like CMOS, and unwanted diffusion or migration of atoms from adjacent layers of different materials, or thermal stresses induced by temperature because of different coefficients of thermal expansion between different materials.

In the prior art, one of the possible approaches to solve these problems is represented by separating the getter and the device into two compartments formed within the package, or by using localized heating methods such as laser heating or electrical Joule heating with a consequent increase of costs and complexity of the obtained systems.

Another possible solution is represented by the development of a low-temperature vacuum micropackaging wafer-level or chip-to-wafer process for a VOx-based (vanadium mixed oxide) microbolometer detector, as described in “Low-temperature vacuum hermetic wafer-level package for uncooled microbolometer FPAs” (Proceedings of the SPIE vol. 6884, paper 68840P), in which the microbolometer chip exposure temperature does not exceed 140° C.

Moreover, U.S. Pat. No. 8,395,229 related to a MEMS microdevice integrated in a hermetic enclosure, describes an active thin-film getter used for controlling the internal gas composition and pressure wherein the MEMS-based microdevice allows localized heating of the thin-film getter material deposited on its surface. However, even with said specific configuration, it is known in the state of art that, due to the microdevices structure and the relative distances between their single elements, if the getter is not shielded it is not possible to avoid the heating by radiation and the consequent damage to its surroundings.

A further approach is then represented by the choice of the getter composition itself, as disclosed for example in EP0869195 in the name of the applicant, in which a non-evaporable getter alloy comprising zirconium, cobalt and one or more components selected among yttrium, lanthanum or rare earths is used to sorb a wide variety of gases while maintaining a relatively low activation temperature. However, the main drawback of said composition is represented by the presence of cobalt as one of the main components due to its known toxicity for human body.

Therefore, the goal of the present invention is to overcome the above-described problems of the prior art and, particularly, to simplify the manufacturing of MEMS devices.

Object of the present invention is therefore to provide a substrate comprising a base and an integrated getter film for manufacturing microelectronic, microoptoelectronic or micromechanical devices, wherein said getter film allows a gas control and reduction (mainly carbonated species, like carbon oxide and carbon dioxide which are the main species inside sealed devices) while maintaining both a low activation temperature, specifically in the range of 250-300° C., and a reduced activation time, i.e. not higher than 20 minutes, required by the MEMS technology field. It is important to point out that said temperature range also corresponds to the typical sealing temperature of the package.

Therefore, it is possible to both avoid the device damage and reduce the power budget of the sealing process, resulting in quicker processes thus increasing the throughput of manufacturing. Another important improvement related to a lower activation temperature of the getter material is the reduction also of outgassed species from the inner surfaces of the sealed device.

Specifically, said surprising effect can be reached when the getter film composition comprises Zr in an amount comprises between 65% at and 80% at, V in an amount comprised between 15% at and 25% at, a third element selected between Al and Fe in an amount comprised between 2% at and 15% at, and the getter film structure is characterized by a surface roughness comprised between 2 and 20 nm. As confirmed by the examples and comparative samples reported below, the morphologic aspect of the getter film is particularly relevant for the surface interaction with the gases and for their relative absorption values. The average roughness values have been measured by optical profilometer or atomic force microscopy (AFM) and, also considering the sputtering technique employed, may range from 2 nm up to 20 nm, preferably up to 8 nm. The high roughness values can be obtained for thick films, characterized by a thickness from 10 μm.

In preferred embodiments, the third element is Al in an amount comprised between 2% at and 15% at; while in a further embodiment the third element is Fe, preferably in an amount comprised between 2% at and 10% at.

Moreover, minor amounts of impurities of other chemical elements can be present in the getter composition if their overall percentage, intended as the sum of the atomic percentage content of all these chemical elements, is less than 1% at with respect to the total of the getter composition.

According to the present invention, the getter film has a thickness comprised between 500 nm and 10 μm, preferably between 1 μm and 5 μm, while the base has a thickness comprised between 20 μm and 5 mm.

In a further embodiment the base is made of silicon, germanium, soda lime or borosilicate glass, quartz, metals or metallic alloys, like Kovar or Nicrofer and all these materials can be bare or covered, fully or partially, with other metal layers, like gold, aluminum, anti-reflecting coating, oxides.

According to the present invention, the getter film can be deposited by a sputtering deposition technique, which is the most appropriate approach for deposition of (getter) films at industrial level for mass production. The technology is a Physical Vapor Deposition (PVD) that allows to deposit thin films by ionic bombardment of a target material and depositing it onto a substrate.

The ionic bombardment is achieved by generating a plasma in proximity of the target surface, with the ions that are accelerated towards the target by means of electric field and their impact on the target surface results in ejection of atoms from the surface that travel in the opposite direction, where a base is generally placed to collect the sputtered atoms from the target. The target material is the source of atoms to be deposited and it can be made of one single element or alloys. The target is coupled to a backing plate that has the function of providing electrical power to the target and also to dissipate the heat generated by the plasma because of the ion bombardment process. Therefore, the target material must withstand stresses related to thermal heating and cycling as well as stresses induced by different thermal expansion between the target material and the backing plate, which is typically made of copper.

In a second aspect thereof, the invention consists in a micromechanical device comprising a substrate where the getter film is integrated by PVD deposition technics, like sputtering. Other different deposition technologies can be also used, which are typical of the electronic and semiconductor industries, like evaporation.

The base geometry can be flat, like in the case of silicon, germanium or glass and quartz wafers or ceramics, or it can be made of multitude of recesses or cavities created from the flat support with standard etching processes or deep reactive ion etching processes. The cavity depth can typically range from about 10 μm to about 350 μm. When the base is made of recesses or cavities the getter film layer can be deposited at the bottom of the cavity or, as an alternative solution, it can be deposited inside the whole cavity surfaces, i.e. bottom and vertical surfaces, up to the top. The latter case allows to maximize the getter amount inside the cavity, therefore, maximizing the sorption properties of the material.

In case of metallic or ceramic base, the surface of the base can be flat or it can be a 3D object whose shape can be typically a parallelepiped or a rounded cup form. The getter film is deposited inside all the available surfaces of the 3D object. The getter film can be deposited onto the base, directly in contact with the base material, or partially or totally onto different layers or materials that are present onto the base. The getter film can be geometrically patterned on the base in specific positions and shapes through lithography or metallic masks in order to purposely overlap, or not, specific areas or materials that are present on the surface of said base.

In another configuration, the getter material can be deposited on a thin metallic sheet, and then a small portion of the sheet with the getter can be cut and inserted into the device, with no need of depositing directly the getter on the base.

The sheet material can be steel, stainless steel, Kovar or Nicrofer. The sheet thickness is typically in the range of 50-500 μm. In order to simplify the cutting of the sheet in smaller pieces, the sheet can be patterned in smaller pieces of different geometries with chemical etching processes. The smaller shaped pieces are fixed to the sheet frame typically in two points and it is possible to easily remove one single piece by cutting the two anchoring points. The getter material can be deposited on the patterned sheet, and it can be deposited on one or both sides of the pieces. In this configuration the getter film can be activated also with electrical current or laser heating directly, after the sealing process of the device.

Hereinafter, the invention will be explained in more detail with reference to the following examples.

### SAMPLES S1-S3 AND COMPARATIVE SAMPLES C1-C6

The getter film is prepared by sputtering deposition inside a vacuum chamber, where a sputtering target made of ZrVAl material is mounted onto a copper backing plate. The diameter of the sputtering target is 5 cm, and the base where the getter film is deposited is a silicon disk of 2.5 cm diameter. The process gas is Argon for samples S1-S3 and comparative samples C1 and C3-C6, while it is Kripton for C2. The gas flow is 30 or 40 sccm, while the gas pressure is 30 m Torr. Sputtering power is comprised between 120 and 150 W, the distance between the target surface and the base is in the range of 50 mm and the resulting getter film thickness is about 2.0 μm.

The functional properties of the material are characterized by the amount of gas that the getter can absorb at room temperature, after being activated at a specific temperature for a specific time. The test is carried out following the standard ASTM F798-82. The testing gas is carbon monoxide CO, the getter is activated at 250° C. for 15 minutes in vacuum before exposing the material to CO gas.

The resulting absorbed gas amounts reported in Table 1 are normalized to the getter surface.

TABLE 1

| | | | | | | Rare | | |
|---|---|---|---|---|---|---|---|---|
| | Zr | V | Al | Fe | Co | Earths | Roughness | CO abs. |
| Ref | [% at] | [% at] | [% at] | [% at] | [% at] | [% at] | (nm) | [cm³ · Torr/cm²] |
| S1 | 73 | 18 | 9 | — | — | — | 3.4 | 0.40 |
| S2 | 77 | 16 | 7 | — | — | — | 4.0 | 0.47 |
| S3 | 76 | 20 | — | 4 | — | — | 3.0 | 0.44 |
| C1 | 50 | 35 | 15 | — | — | — | 3.0 | 0.11 |
| C2 | 56 | 39 | — | 5 | — | — | 3.1 | 0.24 |
| C3 | 75 | — | — | — | 22 | 3 | 3.0 | 0.17 |
| C4 | 77 | 16 | 7 | — | — | — | 1.1 | 0.001 |
| C5 | 50 | 34 | 16 | — | — | — | 2.4 | 0.03 |
| C6 | 50 | 34 | 16 | — | — | — | 0.7 | 0.001 |

The reported results point out that samples S1-S3, prepared according to the present invention, show a significant CO absorption and a consequent relevant reduction of said gas species, while maintaining reduced time and temperature of activation.

On the contrary, comparative samples C1, C2 and C5, activated in the same way and having a comparable roughness, but characterized by a different composition of the getter film, reveal lower gas absorption values and a consequent reduction of efficiency. At the same time, comparative examples C4 and C6 disclose the key role of the specific range of surface roughness for the invention, since substrates characterized by roughness values lower than 2 nm show a significant decrease of gas absorption. Also comparative sample C3, which reports a typical getter composition comprising cobalt according to the prior art, in addition to the toxicity problems related to the use of said metal, achieves a lower gas absorption despite having the same roughness as S3.

1. A substrate, comprising:
a base; and
an integrated getter film for manufacturing microelectronic devices;
wherein:
the getter film consists of:
Zr in an amount of 65 at % to 80 at %;
V in an amount of 15 at % to 25 at %;
a third element selected from the group consisting of Al and Fe in an amount of 2 at % to 15 at %; and
optional impurities of one or more other chemical elements that can be present in the getter composition at an overall percentage that is less than 1 at % with respect to the total of the getter composition; and
the getter film has surface roughness values of 2 nm and 20 nm.

2. The substrate according to claim 1, wherein the third element is Fe in an amount at % to 10 at %.

3. The substrate according to claim 1, wherein the getter film has a thickness of 500 nm to 10 μm.

4. The substrate according to claim 1, wherein the base has a thickness of 20 μm to 5 mm.

5. The substrate according to claim 1, wherein the base is made of at least one material selected from the group consisting of silicon, germanium, a ceramic, soda lime glass, borosilicate glass, quartz, a metallic element, Kovar, steel, stainless steel, and Nicrofer.

6. The substrate according to claim 1, wherein a surface of the base is a flat surface or a 3D object with a parallelepiped or a rounded cup form.

7. The substrate according to claim 1, wherein the getter film is deposited by a sputtering technique.

8. The substrate according to claim 1, wherein a material of the base is covered, fully or partially, with one or more metal layers selected from the group consisting of gold, aluminum, an anti-reflecting coating, and an oxide.

9. The substrate according to claim 1, wherein the getter film is geometrically patterned on the base in specific positions and shapes.

10. A micromechanical device comprising the substrate according to claim 1.

11. A method of manufacturing micromechanical device, comprising incorporating the substrate according to claim 1 as an element.

12. The substrate according to claim 1, wherein the getter film has surface roughness of 2 nm to 8 nm.

13. The substrate according to claim 1, wherein the getter film has a thickness of 1 to 5 μm.

14. The substrate according to claim 1, wherein a surface of the base comprises is a cavity having a depth of 10 μm to 350 μm.
